(19) United States
(12) Patent Application Publication
(10) Pub. No.: US 2022/0350252 A1
(43) Pub. Date: Nov. 3, 2022

(54) PROCESS FOR HYBRID SURFACE STRUCTURING BY PLASMA ETCHING

(71) Applicant: COMMISSARIAT A L'ENERGIE ATOMIQUE ET AUX ENERGIES ALTERNATIVES, PARIS (FR)

(72) Inventors: Hubert TEYSSEDRE, Grenoble (FR); Nicolas POSSEME, Grenoble (FR); Zouhir MEHREZ, Grenoble (FR); Michael MAY, Grenoble (FR)

(73) Assignee: COMMISSARIAT A L'ENERGIE ATOMIQUE ET AUX ENERGIES ALTERNATIVES, PARIS (FR)

(21) Appl. No.: 17/660,099

(22) Filed: Apr. 21, 2022

(30) Foreign Application Priority Data
Apr. 30, 2021 (FR) 21 04582

(51) Int. Cl. G03F 7/40; G03F 7/00; G03F 7/20

(52) U.S. Cl. CPC G03F 7/40; G03F 7/0002; G03F 7/2059; G03F 7/70025

(57) ABSTRACT

A process for producing a hybrid structured surface, including depositing, on a substrate, a layer of mineral resin including a proportion of Si and/or of SiO₂ includes between 1% and 30% by molar mass; forming a structure including a plurality of pattern motifs in that layer, having at least one dimension, measured parallel or perpendicular to the substrate, includes between 50 nm and 500 μm; forming a roughness on at least part of the surface of the pattern motifs.

### TECHNICAL FIELD AND PRIOR ART

The invention concerns the structuring techniques that enable a hybrid structure to be produced, comprising for example pattern motifs at micrometric scale and etching at least part of these pattern motifs in order to give them a nanometric scale roughness.

This type of hybrid structure in particular makes it possible to create a surface which has antibacterial and antiviral properties, with rough texturing which is controlled over at least part of the surface of the pattern motifs.

Antibacterial surfaces are generally created either by plasma depositions with precursors rich in Si (by “HMDSO” plasma) (see the paper by Zouaghi et al. 2018, Applied Surface Science, Volume 455, 15 Oct. 2018, Pages 392-402: “Atmospheric pressure plasma spraying of silane-based coatings targeting whey protein fouling and bacterial adhesion management”), or by laser ablation of a metal surface (S. Moradi et al.; ACS Appl. Mater. Interfaces 2016, 8, 27, 17631-17641, Jun. 20, 2016, https://doi.org/10.1021/acsami.6b03644: “Effect of Extreme Wettability on Platelet Adhesion on Metallic Implants: From Superhydrophilicity to Superhydrophobicity”), or by electrolysis to produce the porous oxide (Thukkaram et al., ACS Appl. Mater. Interfaces, 2020: “Fabrication of microporous coatings on titanium implants with improved mechanical, antibacterial and cell-interactive properties”). Also known is the paper by Dionysia Kefallinou et al. “Optimization of Antibacterial Properties of ‘Hybrid’ Metal-Sputtered Superhydrophobic Surfaces”, Coatings 2020, 10, 25, 30 Dec. 2019.

None of these known techniques enables simple creation on a substrate of a surface that has both micropatterning and a finer structure, at the nanometric scale.

### DISCLOSURE OF THE INVENTION

The invention first of all concerns a process for producing a hybrid structure comprising:
a) depositing a layer of mineral resin on a substrate, this layer comprising a proportion of Si and/or of SiO₂, which is preferably comprised between 1% and 30% by molar mass.
b) forming a structure comprising a plurality of motifs or pattern motifs of that layer, for example micrometric pattern motifs;
c) forming a roughness on at least part of the surface of these pattern motifs.

Preferably, the roughness is at least in part formed by consumption, or etching, of part of the mineral phase.

The polymerization of the resin may take place between the 2 steps b) and c).

Each pattern motif (which may be referred to as being micrometric) preferably has at least one dimension, measured parallel or perpendicular to the substrate, comprised between 100 nm and 1 μm or even up to 500 μm. The pattern motifs may thus be referred to as “micrometric”.

The pattern motifs may be produced in the layer of mineral resin for example by an optical or electron-beam lithography process, or for instance by a nanoprinting or nanoimprinting technique.

The pattern motifs, which may for example be micrometric, may have either a crenellated, conical, pyramidal or other form. These pattern motifs makes it possible to obtain a de-wetting surface on which bacteria do not adhere, which may be further reinforced by grafting.

In an application to bacteria, their denaturing may result from the roughness (nanostructure) but may also be obtained/strengthened by the pattern motifs having projecting shapes (cones or pyramids) for example.

The roughness (constituting nanometric structuring with a critical dimension for example less than 50 nm) may be obtained for example by an oxidizing process, of the kind comprising at least one species or a gas making it possible for the mineral phase of the resin to be consumed to a greater or lesser extent, and thereby to reveal regions having absences of Si and/or SiO₂ atoms or molecules. These Si and/or SiO₂ atoms or molecules are not consumed by this oxidizing process (it being nevertheless possible for the Si atoms to be oxidized to SiO₂). This oxidizing process is for example by isotropic or anisotropic plasma etching.

According to the invention, 2 steps or levels of structuring are thus employed:
during step b), a lithography or nanoimprinting technique applied to the mineral resin (preferably containing a controlled proportion of Si and/or of SiO₂, comprised between 1 and 30% by molar mass) to have pattern motifs, preferably at the micrometric scale, of which the shape, period and dimensions are defined by the parameters of that process;
during step c), a random roughness is generated at the surface of said pattern motifs, by removing carbon-containing parts, for example by virtue of an oxidizing process, by way of further example, an oxidizing plasma, which may be isotropic or anisotropic.

The surface so created is rich in Si and/or in SiO₂, which, in addition to the surface texture so obtained, which is favorable to antibacterial and antiviral applications, makes it possible to graft silanes thereon, for example to change the surface energy properties with a view to increasing the dewetting effect. The silanes thus come to help the dewetting, and thus advantageously complement the pattern motifs or microstructures.

The invention also relates to a hybrid structure, comprising, on a substrate, a layer of mineral resin, this structure comprising:
a plurality of pattern motifs in said layer, each pattern motif being for example a micrometric pattern motif, comprising an upper part and a lower part and being able to have at least one dimension, measured parallel or perpendicular to the substrate, comprised between 50 nm and 1 μm or even 500 μm;
a roughness over at least the upper part of these pattern motifs.

At least some of the roughness may be formed by absence of part of the mineral phase, for example further to the consumption or etching thereof.

In such a hybrid structure, the mineral resin layer comprises Si and/or SiO₂, in a proportion which may be comprised between 1% and 30% by molar mass, but of which the distribution within the layer of mineral resin is not necessarily homogenous.

The roughness constitutes nanometric structuring with a critical dimension for example less than 50 nm.

In a hybridization process or structure according to the invention:
the substrate may for example be of silicon or of a cross-linked negative resin or of glass.
and/or the roughness may be on the upper part and the lower part of the pattern motifs and optionally on the lateral walls that link these upper and lower parts;
and/or the roughness may have an average value comprised between 0.5 nm and 30 nm;
and/or the neighboring pattern motifs may be separated by a distance comprised between 50 nm and hum or even 500 μm;
and/or the bottom (or lower part) of the pattern motifs may constitute resin in which the pattern motifs are formed, or may be the surface of said substrate;
and/or at least one fluorinated agent or silane may be grafted onto at least part of the surface.

### BRIEF DESCRIPTION OF THE DRAWINGS

FIGS. 1A and 1B represent examples of nanoimprinting in a mineral resin having 4% Si and/or SiO₂,

FIGS. 2A and 2B represent an example of mineral resin post-printing, with illustration of the presence of the Si and/or SiO₂ components; before (FIG. 2A) and after (FIG. 2B) implementation of the oxidizing process;

FIGS. 3-5 represent SEM images (FOV=3 μm) of surfaces obtained by an etching process without bias, with different plasmas, without (FIG. 3) or with (FIGS. 4, 5) fluorinated species;

FIG. 6 represents the change in roughness Ra (in nm) of the surface of a resin treated according to the invention for a process time of 200 seconds and SF₆/O₂ ratios comprised between 0 and 3:25;

FIGS. 7-8 represent examples of treatment according to the invention, applied to surfaces having a proportion of Si and/or SiO₂ that is too great to obtain a hybrid structure according to the invention;

FIGS. 9-10 represent examples of treatment according to the invention, applied to surfaces having a proportion of Si and/or SiO₂ that is adequate to obtain a hybrid structure according to the invention;

FIGS. 11-12 represent variants of processes according to the invention.

### DETAILED DESCRIPTION OF SPECIFIC EMBODIMENTS

In the context of the present invention, a mineral resin is preferably chosen containing a proportion of Si and/or of SiO₂ (denoted Si/SiO₂ below) comprised between 1% and 30% (in molar mass). As explained later, a resin comprising a higher proportion of Si/SiO₂ may be treated to reduce this by adding an organic compound, such as another resin or a precursor. Furthermore, if a resin comprises an insufficient proportion of Si/SiO₂, implantation of Si is possible to increase it.

The resin chosen, in particular its proportion of Si/SiO₂ comprised between 1% and 30%, is compatible with at least one process of optical or electron-beam lithography or an alternative technique (such as nanoimprinting) to produce a first level of structures. For each resin, a qualification process may be performed relative to each technique for example as described in the paper by Kretz et al. “Comparative study of calixarene and HSQ resist systems for the fabrication of sub-20 nm MOSFET device demonstrators”, which appeared in Microelectronic Engineering, 78-79, 2005, 479-483. As explained later, optical or electron-beam lithography techniques do not make it possible to preserve the resin at the bottom of the pattern motifs, which is however possible with the nanoimprinting technique (in that case, the depth h of the pattern motifs is less than the thickness of the resin layer). The nanoimprinting can also make it easy to produce projecting shapes (cone or pyramid in particular) which will enable bacteria to be denatured.

According to the shape of the pattern motifs desired and their dimensions, and according to the properties of the resin and the technique chosen to form the pattern motifs, the amount of resin to employ as well as the parameters for spreading, exposure, development and the parameters and possible intermediate annealing operations.

The example presented below implements nanoimprinting resins, whether or not commercially available. Thus, the EVG UVA resin may be taken (version 1 to 4). This resin mainly comprises two substances having respectively 3.6 and 0.03% by mass in the material:
Propyl Acrylate Si(OH)₃;
Phenyl bis(2,4,6-trimethylbenzoyl)phosphine oxide.

The resin makes it possible to reproduce pattern motifs:
having a width and/or depth comprised between 50 nm and several hundred micrometers, for example comprised between 50 nm and 500 μm;
for a period (distance separating two neighboring pattern motifs) which may be comprised between 50 nm or 100 nm and several hundred micrometers, for example comprised between 50 nm or 100 nm and 500 μm or even 1 mm.

The resin of this example contains 4% silicon, which is in the appropriate range of 1%-30% to implement a process according to the invention.

The putting into form of this resin by nanoimprinting is performed here by virtue of a mold, for example a flexible mold of PDMS, for example acrylate-based (or another material compatible with that resin) transparent to the 365 nm wavelength (wavelength of photopolymerization, which takes place after nanoimprinting). This may be a mold having the reference EVG AS2, with which cavities 6 may be reproduced, 2 neighboring cavities being separated by a distance of 500 nm, each cavity having a step height h (see FIG. 2A) of 500 nm. These dimensions are given by way of example: more generally, each pattern motif has at least one of its dimensions measured parallel (I) or perpendicular (h) to the substrate, comprised between 50 nm and 1 mm. I may in particular be the width of the cavity opening, measured between the lateral walls 21 thereof; h may be the depth of that cavity, measured between the upper surface 22 of the pattern motif and its lower surface (or its bottom or its lower part) 23.

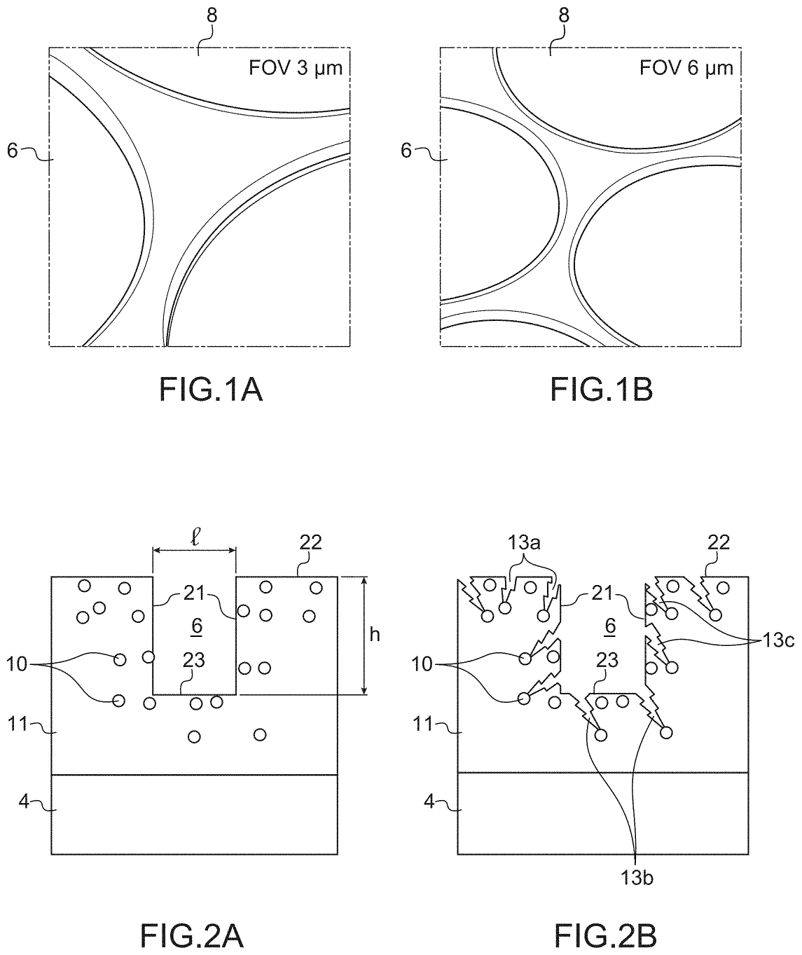

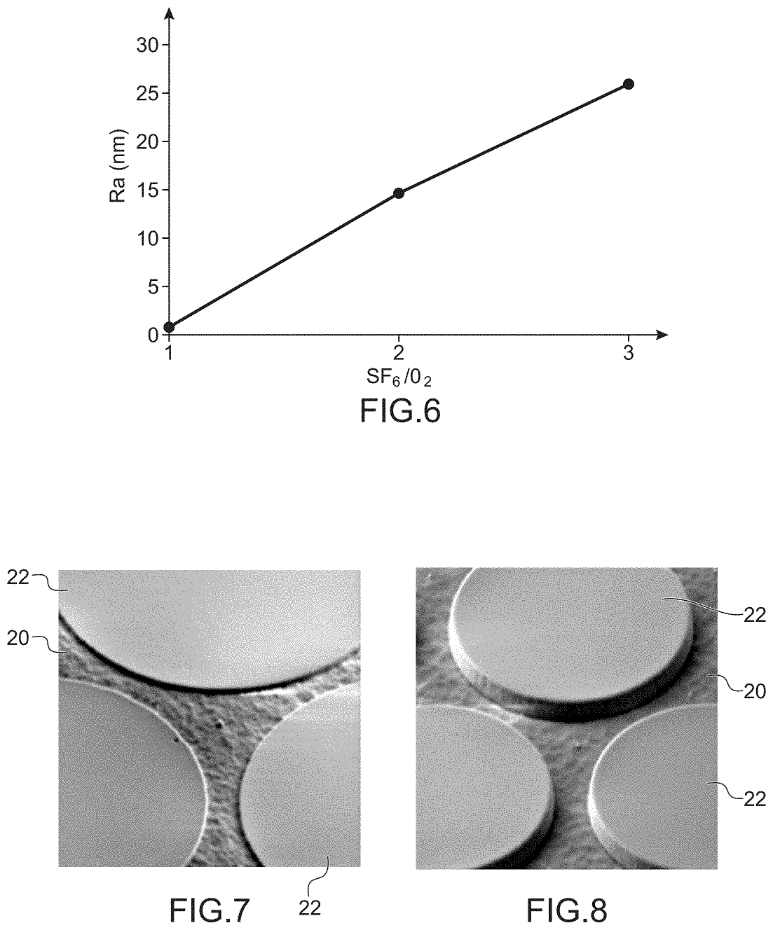

These cavities 6 are illustrated:
in FIGS. 1A and 1B, which are scanning electron microscope (SEM) images, with a field of view (FOV) respectively of 3 μm (FIG. 1A) and 6 μm (FIG. 1B);
more diagrammatically in FIG. 2A, which represents a pattern motif seen in cross-section with distribution of the Si/SiO₂ species (symbolized by light-colored dots) in the polymerized resin 11.

In the example illustrated by these Figures, the parameters used for the process for putting the resin into form are the following (with equipment of “cluster EVG Hercules” type): 500 mbar (pressure corresponding to the lessening of force which is applied to the flexible mold), lamp power 600 mW/cm² (this power may be adjusted, for example between 50 and 600 mW/cm²), for an exposure time of 8s, for an initial thickness of resin of 800 nm.

Any other shape of pattern motif may be produced, for example conical or pyramidal pattern motifs or of other shape. The process implemented is then configured for the desired shape; for example, the shape of the mold is configured to the desired shape of pattern motif.

In order to generate roughness on the pattern motifs produced, an oxidizing process is employed, comprising at least one species or gas making it possible to slightly consume the mineral phase to reveal the regions having absences of Si/SiO₂ compounds. For example, and in non-limiting manner, this gas may be composed of a fluorine-containing component (CF₄, SF₆) and the Oxygen/Fluorine ratio may be modified in order to vary the roughness. FIG. 2B represents the pattern motif of FIG. 2A, produced in the mineral resin 11, after implementation of the oxidizing process: references 13a, 13b, 13c designate the roughnesses obtained (these are of course diagrammatic representations), both on the upper parts 22 of the pattern motifs, and on the flanks 21 or on the bottom 23.

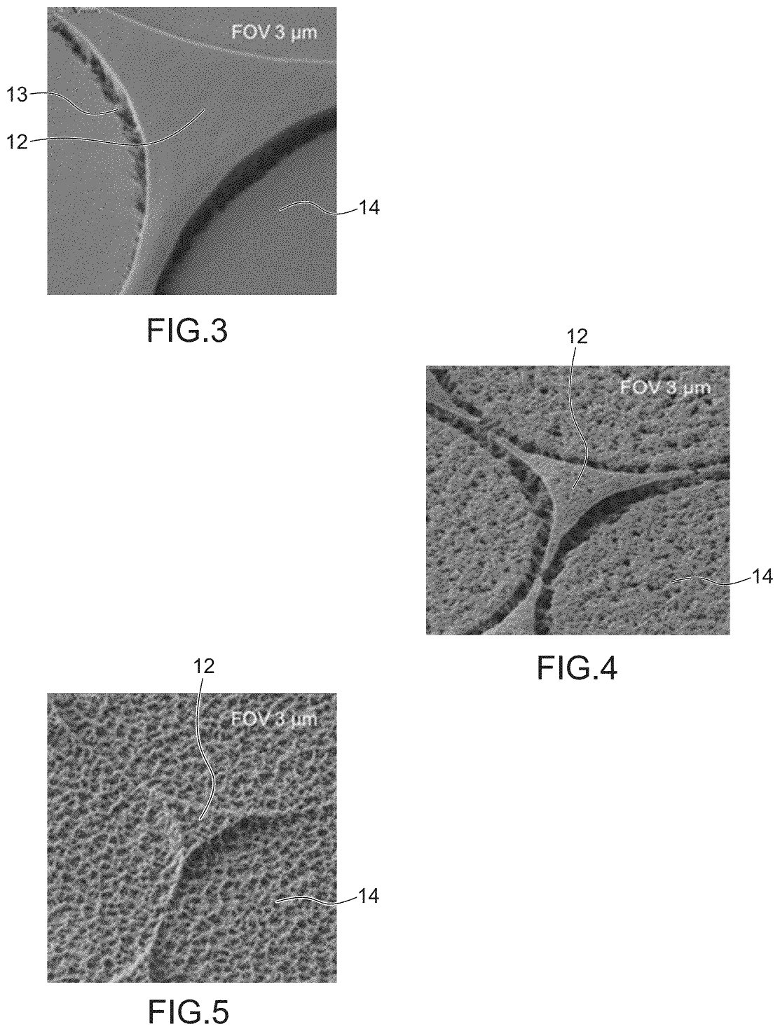

FIGS. 3-5 are comparative examples, for a commercially-available resin having a content of 4% by molar mass (version 4 of the UVA from EVG). These 3 Figures are SEM images (FOV=3 μm), and correspond to the implementation of various plasmas, without bias, at low temperature (for example comprised between 50° C. and 60° C.) for an etching time of 200 sec:
FIG. 3 corresponds to an O₂ plasma, without a fluorine-containing species; it can be seen in this Figure that the gas has slightly consumed the resin at the foot of the pattern motifs, but has not modified the roughness of the upper part nor of the lower part of the pattern motifs; the regions at the feet of the pattern motifs are stressed regions, in which the polymer chains may have undergone elongation and in which the silicon is distributed less homogenously than elsewhere, which may explain the etching in these regions;
FIG. 4 corresponds to the implementation of a SF₆/O₂ plasma with a ratio of 1/25; it can be seen in this Figure that the gas has consumed the resin in all parts and the average roughness Ra obtained at the surface is 15 nm; in this Figure, as in FIG. 5, the Si has oxidized into SiO₂, which is not consumed;
FIG. 5 corresponds to the use of an 5F₆/O₂ plasma with a ratio of 3/25; it can be seen in this Figure that the gas has attacked the resin in all parts and the average roughness obtained at the surface is 25 nm; it is thus greater than in the case of FIG. 4, for which the proportion of SF₆ was lower.

More generally, FIG. 6 shows the change in the average roughness Ra obtained at the surface as a function of the SF₆/O₂ ratio (this latter changing between 0:25 and 3:25, with an intermediate point of 1:25) this being the case for the same resin as that used for the examples of FIGS. 3-5. According to this Figure, it can thus be seen that it is possible to linearly adjust the average roughness obtained, in this example between 0.5 nm and 30 nm. A similar change is obtained for the variable etching times but with a fixed SF₆/O₂ ratio.

The use of a resin with too high a content of Si/SiO₂ does not enable the desired roughness to be obtained (for example SiArc with 40-50%, also designated by JSR ISX412). However, it is possible to reduce this content to bring it back to the desired range, for example by adding an organic compound (resin or precursor).

According to one example, there is used a ISX412 resin and an IRGACURE 4265 precursor from BASF. With 0% added agent (or precursor), this material cannot be imprinted; it becomes possible to imprint it with a proportion of 5 to 15% of added agent, for imprinting times comprised between 20 minutes (with 5% IRGACURE) and 5 minutes (with 15% IRGACURE), under a pressure of 30 bar and at 100° C.

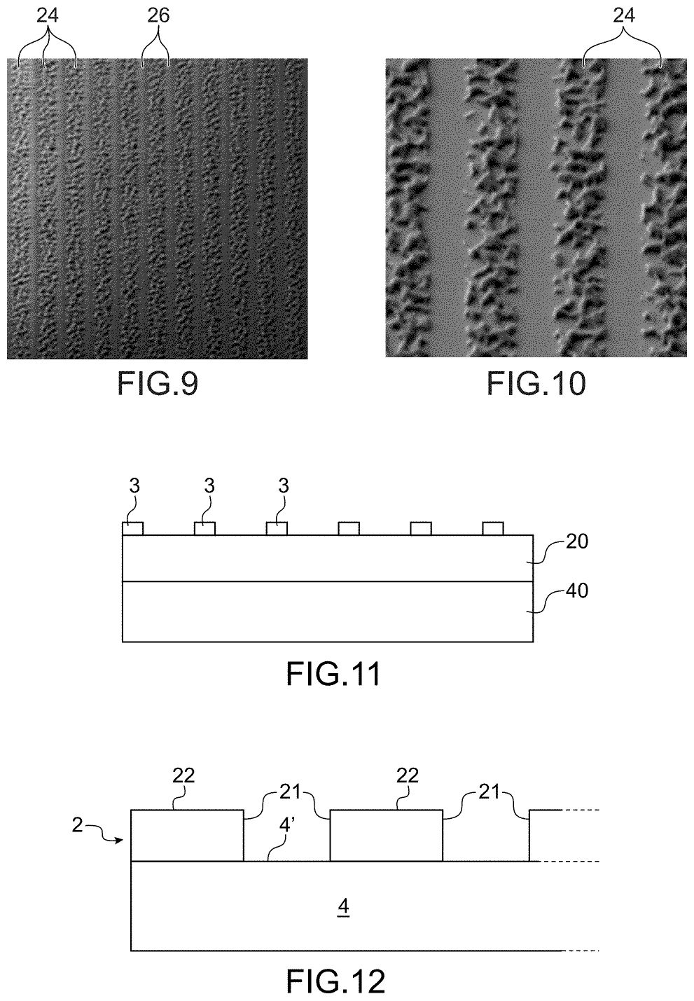

In FIGS. 7-10, examples are presented with 5% IRGACURE (FIGS. 7 and 8) and with 15% IRGACURE (FIGS. 9 and 10, in which the pattern motifs are produced in the form of parallel bands), in which the resin is imprinted, then the entirety may be covered with an organic resin 20 (which makes it possible to protect the underlying substrate to carry out a later treatment solely on the upper part of the pattern motifs).

An etch-back step is applied to make the upper parts 22 of the imprinted pattern motifs re-appear, as illustrated in FIG. 7; however the roughness is not revealed (as too high a proportion of SiO₂, greater than 30%), and it is not revealed by extending the etching either (under O₂/HBr plasma, with a bias of 500 W) as presented in FIG. 8.

Using the formulation with 15% IRGACURE the roughness of the upper part of the pattern motifs 24 is revealed as one of the etch-back step (FIG. 9) (since the proportion of Si/SiO₂ is in the range 1-30%), and it is possible to completely remove the organic part 26 simply by extending the etching time (FIG. 10; also under O₂/HBr plasma with a bias of 500 W).

From FIGS. 7-10 it can be concluded that the amount of Si/SiO₂ may be modulated in order to bring it back under the threshold of 30% (by molar mass) in order to enable the implementation of the process according to the invention.

In the examples described above, the layer of resin 2 is deposited on a substrate 4 (see FIG. 2A) of silicon.

It is possible, as a variant, to deposit the resin on a layer 40 (see FIG. 11) of negative resin, after cross-linking or polymerization of the latter. As above, it is then possible to produce micrometric pattern motifs by nano-imprinting in the layer 2: this technique makes it possible to keep resin at the bottom of the pattern motifs, as in FIG. 2A. As a variant, the micrometric pattern motifs may be produced by optical or electron-beam lithography, with the help of a resist 3, as shown in FIG. 11. In this case, the bottom of the pattern motifs is formed by the upper surface 4′ of the underlying substrate but not by the resin from which the pattern motifs have been formed.

Thus, FIG. 12 represents micrometric pattern motifs formed in a layer 2 of resin, by optical or electron-beam lithography, on a support substrate 4 of silicon, of which the upper surface 4′ constitutes the bottom of the pattern motifs.

According to the isotropic or anisotropic character of the plasma, the roughness may be formed only on the upper parts 22 of the pattern motifs (FIG. 12), or both on the upper parts 22 and the lateral parts 21. Similarly, in the context of FIG. 2B above, the roughness may be formed solely on the upper part 22 and lower part 23 of the micrometric pattern motifs, or also on the lateral parts 21, using an anisotropic plasma.

A structured surface obtained according to the invention makes it possible to graft fluorine-containing agents (which assist in dewetting and thus in the evacuation of “dead” bacteria more easily in a solvent such as water) or silane. The grafting takes place on the nanometric pattern motifs.

Whatever the embodiment chosen, the pattern motifs may have various shapes, for example circular, as illustrated in FIGS. 1A-1B, 7, 8 or in the form of bands that are parallel to each other, as illustrated in FIGS. 9, 10.

A property of a structured surface obtained according to the invention is that viruses cannot adhere thereto on account of the microstructures and the grafting carried out at the surface; the viruses are furthermore damaged by the roughness (nanometric structure) and, if any, by the microstructure when this is of projecting form.

1-16. (canceled)

17. A process for producing a hybrid structure comprising:
forming, on a substrate, a layer of mineral resin comprising a proportion of Si and/or of SiO₂ comprised between 1% and 30% by molar mass;
forming a structure comprising a plurality of pattern motifs in that layer, having at least one dimension, measured parallel or perpendicular to the substrate, comprised between 50 nm and 500 μm;
forming a roughness on at least part of the surface of the pattern motifs, by consumption of some of the mineral phase.

18. The process according to claim 17, the roughness being obtained by an oxidizing process comprising at least one species or gas enabling some of the mineral phase to be consumed.

19. The process according to claim 18, said oxidizing process employing a fluorine-containing component.

20. The process according to claim 19, said oxidizing process employing SF₆ and/or CF₄.

21. The process according to claim 20, said oxidizing process employing SF₆, with a ratio of SF₆/O₂ comprised between 1:25 and 3:25.

22. The process according to claim 17, the roughness of the pattern motifs being obtained by isotropic or anisotropic plasma etching.

23. The process according to claim 17, the substrate being of silicon or of a cross-linked negative resin.

24. The process according to claim 17, said plurality of pattern motifs in the layer of resin being obtained by nanoimprinting, or by optical or electron beam lithography.

25. The process according to claim 17, the average roughness obtained on at least part of the pattern motifs being comprised between 0.5 nm and 30 nm.

26. The process according to claim 17, neighboring pattern motifs being separated by a distance comprised between 50 nm and 1 mm.

27. The process according to claim 17, further comprising a step of grafting at least one fluorine-containing agent or silane.

28. A hybrid structure, comprising, on a substrate, a layer of mineral resin, said structure further comprising:
a plurality of pattern motifs in said layer of mineral resin, each pattern motif comprising an upper part and a lower part and having at least one dimension, measured parallel or perpendicular to the substrate, comprised between 100 nm and 500 μm.
a roughness, corresponding at least in part to an absence of some of the mineral phase, over at least the upper part of those pattern motifs.

29. The hybrid structure according to claim 28, the substrate being of silicon or of a cross-linked negative resin.

30. The hybrid structure according to claim 28, the roughness being on the upper part and the lower part of the pattern motifs and optionally on the lateral walls that link these upper and lower parts.

31. The hybrid structure according to claim 28, the roughness having an average value comprised between 0.5 nm and 30 nm.

32. The hybrid structure according to claim 28, neighboring pattern motifs being separated by a distance comprised between 50 nm and 1 mm.
